(19) United States
(12) Patent Application Publication
(10) Pub. No.: US 2024/0290143 A1
(43) Pub. Date: Aug. 29, 2024

(54) SYSTEMS AND TECHNIQUES FOR APPLYING SCENE SELECTORS TO ROAD DATA AND SIMULATION DATA FOR CHARACTERIZING AUTONOMOUS VEHICLE PERFORMANCE

(71) Applicant: GM Cruise Holdings LLC, San Francisco, CA (US)

(72) Inventors: Nicholas Famiglietti, Torrance, CA (US); Katelyn Wolfenberger, San Francisco, CA (US); Pei Xu, Sherman Oaks, CA (US); Changkai Zhou, Mountain View, CA (US); Nestor Grace, San Francisco, CA (US); Kevin Yuwen Tong, Carlsbad, CA (US)

(21) Appl. No.: 18/175,369

(22) Filed: Feb. 27, 2023

(51) Int. Cl. G07C 5/08; G06F 30/20

(52) U.S. Cl. CPC G07C 5/0808; G06F 30/20

(57) ABSTRACT

Systems and techniques are provided for detecting occurrence of traffic scenes and characterizing performance of autonomous vehicles (AVs) in relation to said traffic scenes. An example method includes receiving a collection of data compiled by one or more AVs while navigating a real-world environment, wherein the one or more AVs are configured to execute a first version of AV software; identifying, based on at least one traffic scene selector and the collection of data, a plurality of traffic scene datasets each corresponding to an instance in which the one or more AVs encountered a traffic scene; and determining, based on the plurality of traffic scene datasets, one or more metrics for characterizing an operation of the one or more AVs in relation to the traffic scene.

### BACKGROUND

### 1. Technical Field

The present disclosure generally relates to autonomous vehicles and, more specifically, to using scene selectors to detect occurrence of traffic scenes and characterize autonomous vehicle behavior in relation to the traffic scenes.

### 2. Introduction

An autonomous vehicle is a motorized vehicle that can navigate without a human driver. An exemplary autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 is a diagram illustrating an example system environment that can be used to facilitate autonomous vehicle (AV) navigation and routing operations, according to some examples of the present disclosure;

FIG. 2 is a flowchart diagram illustrating an example process for using scene selectors to detect occurrence of traffic scenes and for characterizing performance of autonomous vehicles in relation to the traffic scenes, according to some examples of the present disclosure;

FIG. 3 is a diagram illustrating an example system for characterizing performance of autonomous vehicles in relation to selected traffic scenes, according to some examples of the present disclosure;

FIG. 4 is a diagram illustrating an example simulation framework, according to some examples of the present disclosure;

FIG. 5 is an example of a deep learning neural network that can be used to implement aspects of scene selectors to detect occurrence of traffic scenes, according to some examples of the present disclosure;

FIG. 6 is a flow chart illustrating an example process for characterizing and predicting performance of autonomous vehicles in relation to selected traffic scenes, according to some examples of the present disclosure; and

FIG. 7 is a diagram illustrating an example system architecture for implementing certain aspects described herein, according to some examples of the present disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

As previously explained, autonomous vehicles (AVs) can include various sensors, such as a camera sensor, a light detection and ranging (LIDAR) sensor, a radio detection and ranging (RADAR) sensor, an inertial measurement unit (IMU), and/or an acoustic sensor (e.g., sound navigation and ranging (SONAR), microphone, etc.), global navigation satellite system (GNSS) and/or global positioning system (GPS) receiver, amongst others. The AVs can use the various sensors to collect data and measurements that the AVs can use for AV operations such as perception (e.g., object detection, event detection, tracking, localization, sensor fusion, point cloud processing, image processing, etc.), planning (e.g., route planning, trajectory planning, situation analysis, behavioral and/or action planning, mission planning, etc.), control (e.g., steering, braking, throttling, lateral control, longitudinal control, model predictive control (MPC), proportional-derivative-integral, etc.), prediction (e.g., motion prediction, behavior prediction, etc.), etc. The sensors can provide the data and measurements to an internal computing system of the autonomous vehicle, which can use the data and measurements to control a mechanical system of the autonomous vehicle, such as a vehicle propulsion system, a braking system, and/or a steering system, for example.

In some cases, an AV may have difficulty autonomously navigating in scenarios that occur infrequently such as temporary traffic scenes. Examples of temporary traffic scenes can include a stopped school bus, a construction zone, a road closure, a human controlling traffic (e.g., police officer or construction worker), an emergency vehicle (e.g., police car, fire truck, ambulance, etc.), a road blockage (e.g., due to a vehicle accident), a traffic redirection, etc. In each instance of such temporary traffic scenes, the AV must detect the scene and adjust behavior to comply with the temporary traffic regulations associated with the scene.

In some cases, identifying the instances in which an AV encounters such a temporary traffic scene would be helpful in order to characterize the behavior of the AV in relation to the traffic scene and/or predict future behavior of the AV in relation to the scene. However, as an AV navigates through its environment the AV is constantly collecting large amounts of data (e.g., LIDAR data, camera data, RADAR data, IMU data, object classifications, trajectory predictions, etc.). Consequently, it may be difficult to identify AV data corresponding to particular scenes of interest such as temporary traffic scenes. Moreover, in some cases the AV may encounter a temporary traffic scene, but the AV data may not be annotated in a manner that facilitates recovery of the AV data.

Systems, apparatuses, processes (also referred to as methods), and computer-readable media (collectively referred to as “systems and techniques”) are described herein for using scene selectors to identify AV data (e.g., road data and/or simulation data) that corresponds to a scene of interest (e.g., a temporary traffic scene). Further, in some aspects, the systems and techniques described herein may be used to characterize and predict the performance of AV in relation to selected traffic scenes based on the AV data.

In some examples, scene selectors may include any type of parameter, variable, factor, element, object, etc. that may be used to identify a scene that is captured by an AV. For example, scene selectors may include an AV detector that corresponds to the output of an AV software module (e.g., a perception stack) that is configured to detect objects in the environment. For instance, the AV detector output may indicate that the AV has identified a temporary traffic condition such as a stopped school bus or a construction zone. In some cases, the scene selectors may also include a confidence level threshold that is associated with the AV detector output. For instance, the scene selector may be used to identify or select AV data corresponding to instances in which the AV is less than 50% confident in a corresponding detection. In some examples, the scene selectors may also include a detection duration. For example, the scene selector may select AV data corresponding to instances in which the AV made a detection for a duration that is greater than 100 milliseconds. In some aspects, the scene selectors may include a scene descriptor, which may correspond to an object type, an object size, an object action, an object orientation, a map location, a time-of-day, etc.

In some examples, the scene selectors can be applied to AV road data and/or AV simulation data to identify one or more scene datasets that correspond to the selected scene. In some cases, the scene datasets can be analyzed to determine AV performance with respect to the scene (e.g., stopping distance from a stopped school bus, compliance with traffic directives from a human controlling traffic, etc.). In some aspects, the AV performance can be characterized using one or more metrics. For example, the AV performance can be characterized by determining statistics such as exposure rate, precision, recall, etc. In some examples, the statistics or metrics may be used to predict future performance of an AV or a fleet of AVs.

In some cases, the scene datasets obtained from AV road data can be used to generate one or more simulated tests. In some examples, the simulated tests may be used to further characterize performance of the AV relative to the scene (e.g., determine further metrics or statistics based on AV simulation data). In some aspects, the characterization of the simulation performance may be used to make new predictions and/or modify predictions. In some cases, the simulated tests may also be used to test new versions of software and/or to correlate the performance of software based on AV road data.

In some examples, characterizing the performance of the AV relative to temporary traffic scenes can be used to modify and improve AV software. For example, the AV software may be modified to detect temporary traffic scenes more quickly and therefore improve the response time to such scenes. In addition, the simulated tests that are based on AV road data corresponding to temporary traffic scenes may improve the software development cycle. Further, the scene selectors may assist in identifying temporary traffic scenes notwithstanding the AV's perception output. Such datasets are helpful for further refining the AV software to improve AV performance.

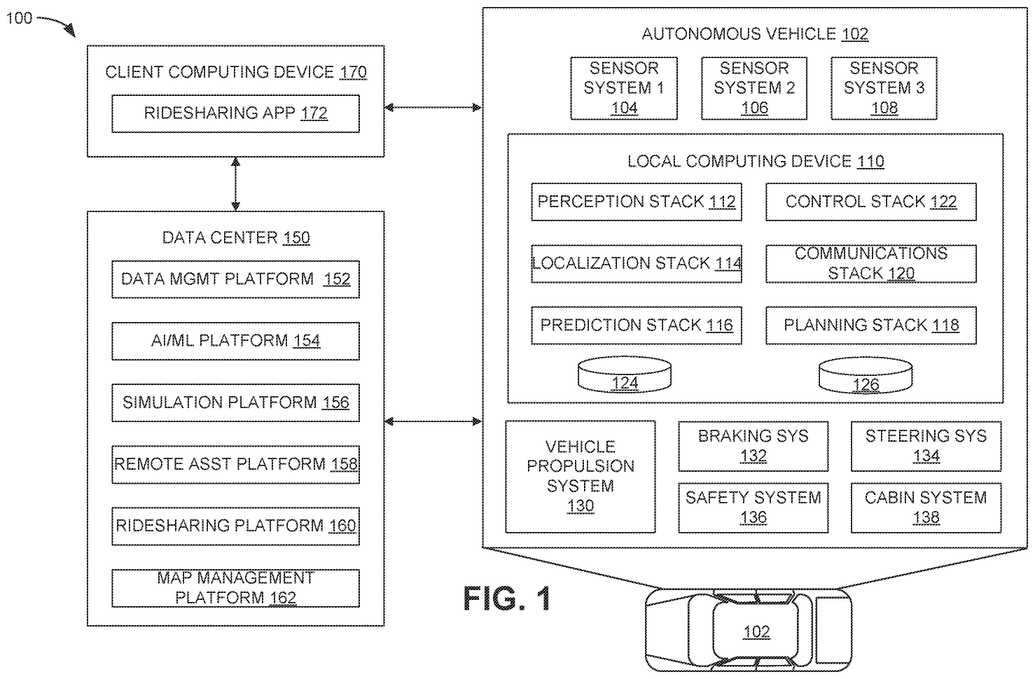

FIG. 1 is a diagram illustrating an example autonomous vehicle (AV) environment system 100, according to some examples of the present disclosure. One of ordinary skill in the art will understand that, for the AV environment system 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV environment system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by sensor systems 104, 106, and 108. The sensor systems 104-108 can include one or more types of sensors and can be arranged about the AV 102. For instance, the sensor systems 104-108 can include Inertial Measurement Units (IMUs), cameras (e.g., still image cameras, video cameras, etc.), light sensors (e.g., LiDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LiDAR system, and the sensor system 108 can be a RADAR system. Other examples may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and/or the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LiDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and/or other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LiDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LiDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LiDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, and a map management platform 162, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from the map management platform 162 and/or a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. In some cases, the client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

Map management platform 162 can provide a set of tools for the manipulation and management of geographic and spatial (geospatial) and related attribute data. The data management platform 152 can receive LiDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some examples, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the ridesharing application 172 to enable passengers to view the AV 102 in transit to a pick-up or drop-off location, and so on.

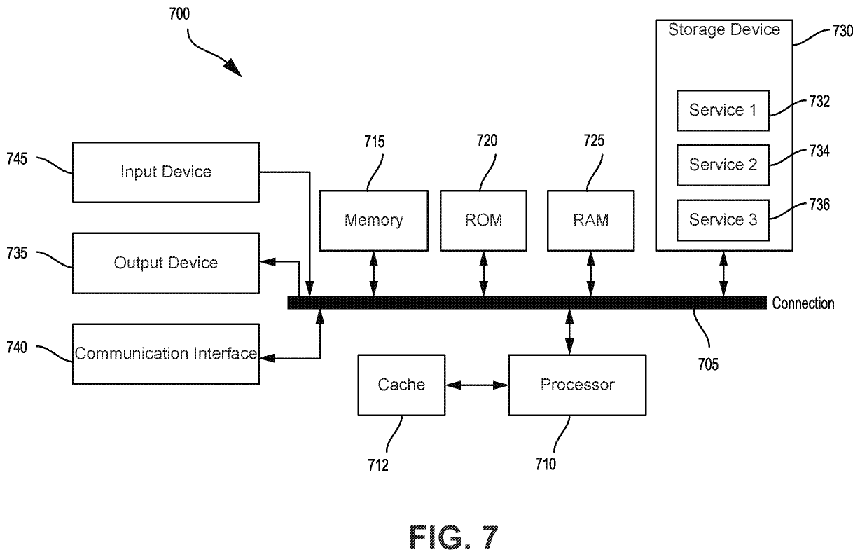

While the AV 102, the local computing device 110, and the AV environment system 100 are shown to include certain systems and components, one of ordinary skill will appreciate that the AV 102, the local computing device 110, and/or the AV environment system 100 can include more or fewer systems and/or components than those shown in FIG. 1. For example, the AV 102 can include other services than those shown in FIG. 1 and the local computing device 110 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 7.

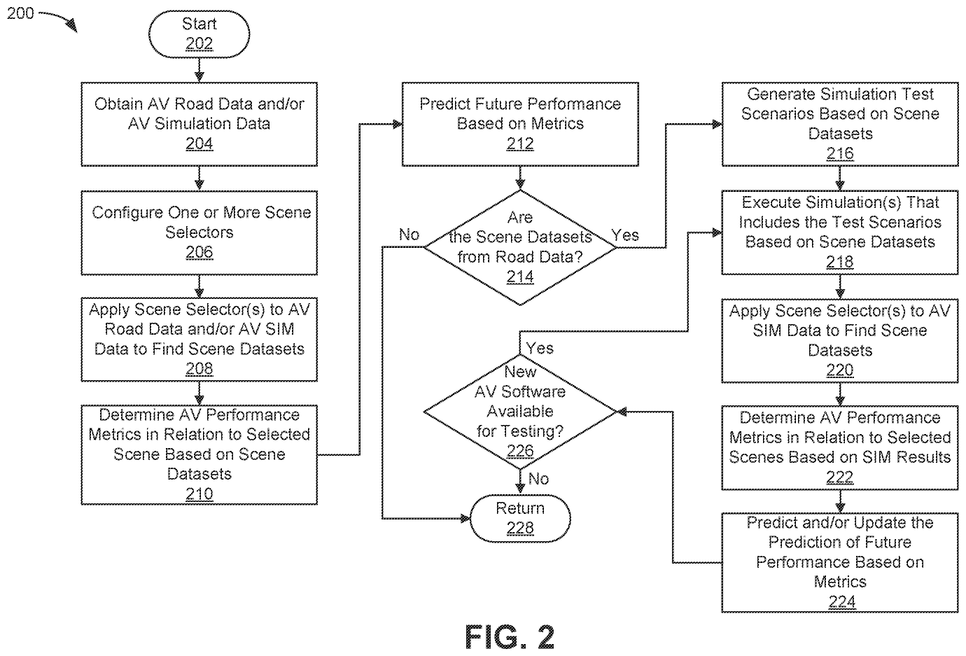

FIG. 2 is a flowchart diagram illustrating an example process 200 for using scene selectors to detect occurrence of traffic scenes and for characterizing performance of autonomous vehicles (AVs) in relation to the traffic scenes. In some aspects, process 200 may start at step 202, which may include initializing of hardware or software systems associated with an AV (e.g., AV 102), with an AV simulation environment (e.g., simulation platform 156), with an AV performance characterization system (e.g., system 300), and/or with any other component or device that may be configured to execute one or more steps in process 200.

In some examples, process 200 may proceed to step 204, which may include obtaining AV road data and/or AV simulation data. In some aspects, AV road data may include any data that is captured, obtained, generated, and/or stored by an AV while operating (e.g., navigating through a real-world environment). For example, AV road data may include sensor data obtained from sensors such as LIDARs, cameras, RADARs, etc. (e.g., sensor systems 104-108). In another example, AV road data may include data corresponding to one or more AV modules, AV components, AV stacks, etc., such as the perception stack 112, the localization stack 114, the prediction stack 116, the planning stack 118, the communications stack 120, and/or the control stack 122. In one illustrative example, AV road data may include one or more of the inputs to the perception stack 112 (e.g., sensor data) and/or one or more of the outputs of the perception stack 112 (e.g., object classification, object position, confidence score, etc.).

In some examples, AV simulation data may include any data that is used, captured, obtained, generated and/or stored while simulating AV operation. For example, AV simulation data can include synthetic sensor data that is used to simulate a real-world environment for testing AV software. In another example, AV simulation data can include data that is generated by the AV software that is being tested by the simulation. For instance, similar to AV road data, AV simulation data can include data corresponding to one or more AV modules, AV components, and/or AV stacks (e.g., data from perception stack 112 and/or any other component associated with the AV).

In some cases, process 200 may proceed to step 206, which may include configuring one or more scene selectors. In some aspects, a scene selector may be used to parse and/or filter AV road data and/or AV simulation data in order to identify AV data corresponding to a traffic scene (e.g., traffic condition, scenario, location, setting, incident, etc.). Examples of traffic scenes include but are not limited to a school bus, a road closure, a construction zone, a human controlling traffic (e.g., police officer, construction worker, etc.), a traffic redirection (e.g., traffic channelization through a temporary lane), a traffic blockage, an emergency vehicle, a traffic maneuver, a road condition, etc.

In some aspects, the scene selectors may be used to identify an output of a stack or module from the AV. For instance, the scene selectors may include an AV detector that is outputted by the perception stack 112. That is, the perception stack 112 may use data from one or more sensors (e.g., sensor systems 104-108) to identify a traffic scene and the perception stack 112 can output an AV detector corresponding to the traffic scene (e.g., an AV detector identifying a stopped school bus). In some instance, the AV road data and/or the AV simulation data can be identified based on the corresponding AV detector.

In some cases, the scene selectors may include a detector confidence level for selecting AV road data and/or AV simulation data based on a confidence score generated by the AV. That is, the AV (e.g., the perception stack 112) may output a confidence score that is associated with the AV detector. For example, the AV may output an AV detector that identifies a human controlling traffic with a corresponding confidence score of 50%. In some aspects, the scene selector may be used to select AV road data and/or AV simulation data based on a threshold confidence level (e.g., scene selector can select AV road data in which confidence score is less than or equal to 75%).

In some configurations, the scene selectors can include one or more scene descriptors. In some cases, a scene descriptor may include an object type, an object size, an object action, an object position, and object orientation, an object location, and/or a map location. For example, the scene descriptors may specify an object type that is detected by the AV such as pedestrians, animals, barricades, cones, motorcycles, trucks, signs, and/or any other type of object. In some cases, the scene descriptor may specify an object size (e.g., minimum, maximum, range, or absolute) using one or more dimensions such as object height, object width, object length. In some instances, the scene descriptor may indicate an object action (e.g., stationary, movement, movement speed, flashing light, etc.) In some aspects, the scene descriptor may indicate a map location. In some cases, the map location may be an absolute location or a location relative to the AV or some other object. In some examples, the map location may correspond to an attribute or label from an HD map (e.g., sidewalk, crosswalk, intersection, lane boundary, school zone, etc.). In some cases, the scene descriptors may be used to identify AV road data and/or AV simulation data corresponding to a scene independent of whether the scene was detected by the AV (e.g., scene selectors can be used independently or in connection with AV detectors and/or detector confidence level).

In some aspects, scene selectors can be used to identify a traffic scene based on one or more heuristics that may be derived from AV data. In one illustrative example, a scene selector (e.g., using one or more scene descriptors) may be used to identify scenes that are likely to include a human traffic controller by identifying scenes that include a pedestrian that is stationary in the roadway and is standing near cones and/or temporary traffic signs. In another example, scene selector may be used to identify scenes that are likely to include a school bus by identifying scenes that include a large vehicle that is stopped with pedestrians nearby and located in the vicinity of a school.

In some cases, process 200 may proceed to step 208, which may include applying the scene selector(s) to AV road data and/or AV simulation data to find scene datasets. In one illustrative example, the scene selector(s) may include scene descriptors such as object dimensions corresponding to a school bus, map location data corresponding to a school bus stop, and object action corresponding to stationary in order to identify AV road data and/or AV simulation data that includes potential school bus vehicles that are stopped at a bus stop. In another example, the scene selector may include an AV detector corresponding to a construction zone. In another example, the scene selector may include an AV detector corresponding to a human controlling traffic while positioned within an intersection.

In some cases, the scene datasets can include sets of AV road data and/or AV simulation data that correspond to the selected scene. For instance, the scene datasets can include the sensor data (e.g., from sensor systems 104-108) collected in connection with the scene. The scene datasets can also include the inputs and/or outputs to one or more of the AV stacks. For example, the scene datasets can include the object classifications outputted by the perception stack 112 in connection with the scene and/or the predicted object trajectory outputted by the prediction stack 116. The scene datasets can include performance metrics associated with the AV within the selected scene. For example, the scene datasets can include the distance between the AV and one or more objects within the scene.

In some aspects, the process 200 may proceed to step 210, which may include determining AV performance metrics in relation to the selected scene based on scene datasets. In some cases, AV performance metrics can be determined for all of the scene datasets while in other cases the AV performance metrics can be determined for a subset of the scene datasets (e.g., by sampling the scene datasets). In some instances, the AV performance metrics can include an exposure rate to the selected scene. In some cases, the exposure rate can be based on the number of times the scene is detected (e.g., using scene selectors) relative to the amount of time the AV is in operation. In some instances, the exposure rate can be based on the number of times the scene is detected relative to distance (e.g., number of miles) the AV drives. In some examples, the exposure rate may also consider the location(s) in which a scene is detected and the amount of time(s) an AV or a fleet of AVs is expected to operate in the location(s). In some cases, the exposure rate may also consider the time(s) of day in which a scene is detected and the number of AVs that are expected to operate during the time(s) of day.

In some aspects, the AV performance metrics can include a precision metric and/or a recall metric. In some cases, the precision metric can be based on the fraction of relevant instances among the retrieved instances. For example, the precision metric can be based on the number of times an AV correctly identified a stopped school bus (e.g., flashing lights) among the total number of times a stopped school bus was identified. In some examples, the recall metric can be based on the fraction of relevant instances that were retrieved. For instance, the recall metric can be based on the number of times an AV correctly identified a construction zone among all of the instances in which the AV encountered a construction zone.

In some cases, the process 200 may proceed to step 212, which can include predicting future performance based on metrics. For example, the exposure rate, the precision metric, and/or the recall metric can be used to predict future performance by an AV or a fleet of AVs. For instance, past exposure rate to a traffic scene (e.g., active school bus) can be used together with metrics (e.g., precision, recall, etc.) to predict future performance of an AV in relation to the traffic scene. In some examples, the predicted future performance can be based on a portion of the scene datasets (e.g., metrics corresponding to a subsample of the datasets) and/or a portion of the AV road data and/or AV simulation data. Alternatively, in some configurations, the predicted future performance can be based on an analysis of all the scene datasets, the AV road data, and/or the AV simulation data.

In some aspects, the predicted future performance can include a prediction associated with the rate of AV compliance events and/or AV non-compliance events. For example, an AV compliance event and/or an AV non-compliance event may be based on the distance between the stopped AV and a temporary traffic condition such as a road blockage or a stopped school bus. In some cases, the predicted future performance can include a predicted impact on other systems that are associated with the AV. For instance, the predicted future performance may indicate predicted effect on the remote assistance platform 158 (e.g., based on the predicted behavior of the AV fleet in relation to the traffic scene). That is, a predicted higher compliance rate (e.g., based on exposure rate, precision metric, recall metric, etc.) may reduce the number of times that the remote assistance platform 158 is engaged.

In some cases, the predicted future performance can be associated with geographic data. For example, AV performance metrics (e.g., precision, recall, etc.) that correspond to a first geographic area can be used to predict future performance in a second geographic area. In one illustrative example, AV performance metrics corresponding to traffic scenes that include school buses in Los Angeles, California can be used to predict AV performance of traffic scenes that may include school buses in Miami, Florida.

In some examples, the process 200 can proceed to step 214 to determine whether the scene datasets are from AV road data. If the scene datasets are not from AV road data (e.g., the datasets are from AV simulation data), the process 200 can proceed to step 228 and return to prior processing, which may include repeating one or more steps from process 200.

In some cases, if the scene datasets are from AV road data, the process 200 can proceed to step 216, which may include generating simulation test scenarios based on the scene datasets. In some aspects, the simulated test scenarios can be generated by extracting data from the scene datasets that can be used for creating a simulated environment that mimics the real-world environment. In some instances, the data that is extracted from the scene datasets may include AV location data, map data, object types in scene (e.g., vehicles, pedestrians, etc.), object actions (e.g., stationary, moving, pedestrian waving, etc.), weather conditions, time-of-day, and/or any other type of data that may be used for recreating a real-world scene in a simulation environment.

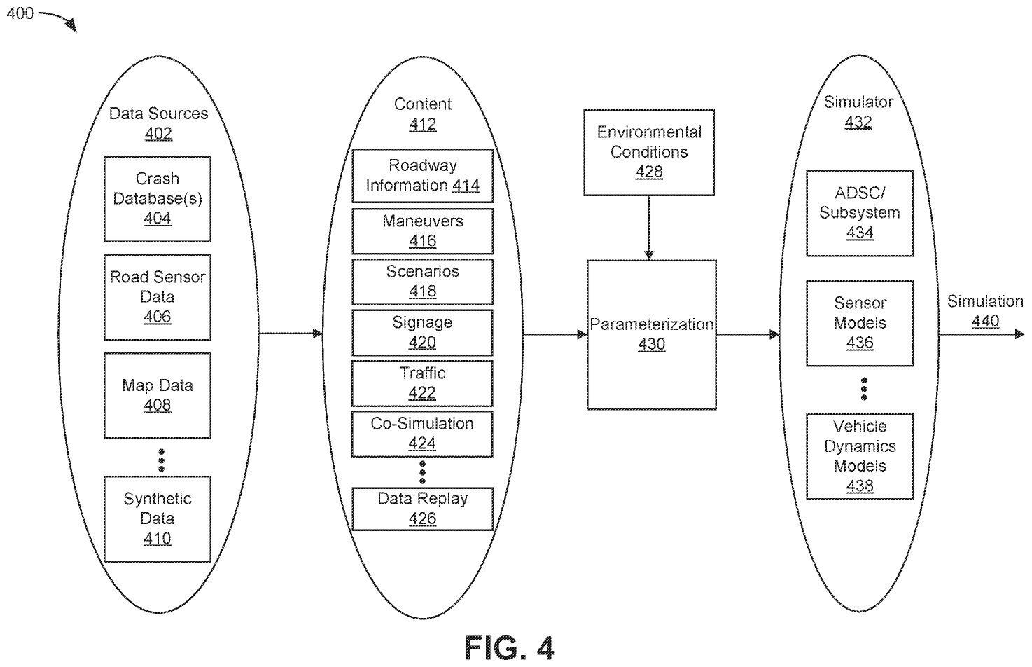

In some examples, the process 200 may proceed to step 218, which can include executing one or more simulated tests that include the test scenarios that are based on the scene datasets. For example, the simulated tests can include test scenarios that are based on scene datasets obtained from AV road data, which may correspond to temporary traffic scenes such as a stopped school bus, a lane closure, a human controlling traffic, a construction zone, etc. In some cases, the simulated tests that are based on the scene datasets may be part of a larger suite of test simulations configured for testing AV software. Alternatively, in some examples, the simulated tests that are based on the scene datasets may be executed independently. In some aspects, the simulated tests may be implemented using a simulation framework such as simulation framework 400 described below in connection with FIG. 4.

In some aspects, the process 200 may proceed to step 220, which can include applying scene selectors to AV simulation data to find scene datasets. As noted above, the scene selectors can include output(s) from a software module or stack (e.g., an AV detector corresponding to a traffic scene), a detector confidence level (e.g., identify scenes wherein AV confidence is above/below a threshold confidence score), and/or scene descriptors (e.g., object type, object dimension(s), object action(s), map location, etc.). For example, the scene selectors can be used to find scene datasets within the AV simulation data corresponding to a traffic scene, an AV behavior, an AV state, an AV performance parameter (e.g., distance to object, acceleration, speed, etc.), any combination thereof, and/or any other aspect that may be part of AV simulation data.

In some configurations, the process 200 may proceed to step 222, which can include determining AV performance metrics in relation to selected scenes based on simulation results. As noted above, the AV performance metrics can include an exposure rate, a precision metric, a recall metric, and/or any other suitable statistical metric.

In some cases, the process 200 may proceed to step 224, which can include predicting and/or updating the prediction of future performance based on the AV performance metrics. For instance, the AV performance metrics obtained from the datasets from the simulation can be used to generate a new prediction of future performance. In some cases, the AV performance metrics obtained from the datasets from the simulation can be used to update a previously determined prediction. For instance, the simulation may correspond to a new software version that improves performance of the AV by reducing the number of non-compliance events that were identified using the AV road data.

In some examples, the process 200 can proceed to step 226 to determine whether new AV software is available for testing (e.g., using the simulation test scenarios based on scene datasets from AV road data). If new software is available, the process 200 may repeat the sequence of steps from step 218 to step 224 using the new software. If no new software is available, the process 200 can proceed to step 228 and return to prior processing, which may include repeating one or more steps from process 200.

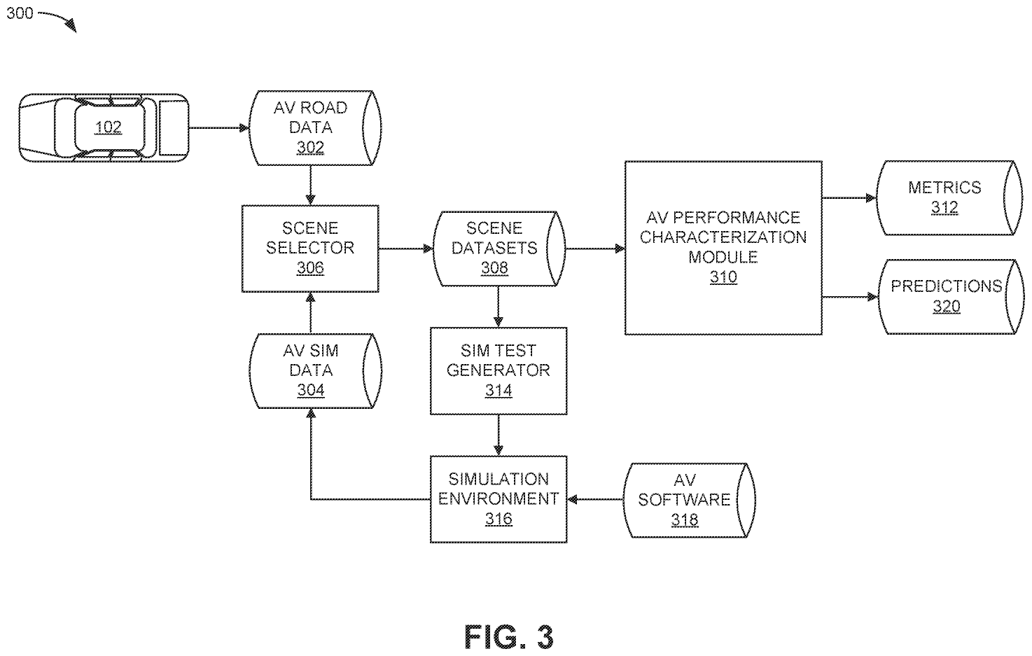

FIG. 3 illustrates an example system 300 for characterizing performance of autonomous vehicles in relation to selected traffic scenes. In some aspects, system 300 may include scene selector 306 that can be configured to receive and process AV road data 302 (e.g., from AV 102) and/or AV simulation data 304 (e.g., from simulation environment 316). In some cases, scene selector 306 can be used to parse and/or filter AV road data 302 and/or AV simulation data 304 to identify scene datasets 308. For example, scene selector 306 may include one or more parameters or criteria that can be used to identify scene datasets 308 that correspond to a traffic scene. In some instances, scene selector 306 may be implemented using a programming language such as structured query language (SQL) or any other suitable programming language for examining AV road data 302 and/or AV simulation data 304.

In some cases, scene selector 306 may include a parameter corresponding to an AV detector (e.g., an output of perception stack 112). Examples of AV detectors can include a stopped school bus, a road closure, a construction zone, a human controlling traffic, a traffic redirection, a traffic blockage, an emergency vehicle, a traffic maneuver, a road condition, any combination thereof, and/or any other object, condition, and/or scene that may be encountered by an AV.

In some examples, scene selector 306 may also include a threshold confidence level that can correspond to AV detectors. For instance, scene selector 306 can be configured to identify scene datasets 308 in which the AV identified a stopped school bus (e.g., AV detector) with a confidence level that is greater than or equal to 50% (e.g., threshold confidence). In this example, scene datasets 308 will not include instances in which the AV identified a stopped school bus with a confidence level that is below 50%.

In some cases, scene selector 306 may also include a time parameter and/or a duration parameter. For example, scene selector 306 can be configured to identify scene datasets 308 in which the AV identified a road closure between midnight and 5:00 AM. In another example, scene selector 306 can be configured to identify scene datasets 308 in which the AV identified a stopped school bus for a duration that is greater than 0.1 seconds. In some configurations, the duration parameter may be used to filter false positives from scene datasets 308.

In some aspects, scene selector 306 can include one or more scene descriptors. In some cases, a scene descriptor may include an object type, an object size, an object action, and/or a map location. For example, scene selector 306 can be configured to identify scene datasets 308 (e.g., from AV road data 302 and/or AV simulation data 304) that include a human controlling traffic by using scene descriptors corresponding to a person (e.g., object type) that is located within an intersection (e.g., map location) and is performing hand gestures (e.g., object action).

In some cases, scene selector 306 may be implemented using a machine learning algorithm. For example, scene selector 306 may include a machine learning model that is configured to identify scene datasets 308 corresponding to a selected traffic scene based on sensor data that is collected by the AV and is part of AV road data 302 and/or AV simulation data 304. In another example, scene selector 306 may include a machine learning model that is configured to identify one or more features associated with a scene that is detected by an AV (e.g., identify object type(s), object action(s), object orientation(s), map location(s), etc. that correspond to a particular traffic scene).

In some aspects, simulation test generator 314 can receive one or more scene datasets 308 (e.g., based on AV road data) and generate corresponding simulated (e.g., data replay) tests that can be executed using simulation environment 316. For example, simulation test generator 314 can use scene datasets 308 to capture features such as map location, detected objects, traffic conditions, weather conditions, time-of-day, etc. that can be used to create simulated tests. In some aspects, simulation environment 316 can execute the new simulated tests as part of a simulation test suite for testing AV software 318. In some instances, simulation environment 316 may generate new AV simulation data 304 based on newly added simulation tests (e.g., from simulation test generator 314) and/or based on newly tested AV software 318.

In some configurations, AV performance characterization module 310 can receive scene datasets 308 and generate metrics 312. In some cases, metrics 312 can include AV performance metrics such as an exposure rate, a precision metric, a recall metric, and/or any other metric. In some instances, metrics 312 can include statistics (e.g., max, min, mean, median, mode, etc.) associated with AV parameters and/or AV performance that is based on scene datasets 308. For instance, metrics 312 can include an average stopping distance of the AV when identifying a blocked traffic lane. In some examples, AV performance characterization module 310 can generate metrics 312 based on all scene datasets 308 or a subsampling of scene datasets 308.

In some aspects, AV performance characterization module 310 can generate predictions 320 of future AV performance based on scene datasets 308 and/or metrics 312. For example, AV performance characterization module 310 can generate predictions 320 based on the exposure rate, the precision metric, and/or the recall metric. In some cases, the exposure rate can be based on number of AVs in fleet, expected time driving versus rate of scene detection, expected miles driving versus miles per scene detection, time(s)-of-day driving versus time(s)-of-day of scene detection, etc.

In some examples, the metrics 312 generated by AV performance characterization module 310 can be used to configure and/or modify the simulation test suite executed by simulation environment 316. For example, a divergence in metrics 312 corresponding to scene datasets 308 taken from AV road data 302 versus scene datasets 308 taken from AV simulation data 304 may be indicative of a test scene that is under-tested or over-tested.

FIG. 4 is a diagram illustrating an example simulation framework 400, according to some examples of the present disclosure. The example simulation framework 400 can include data sources 402, content 412, environmental conditions 428, parameterization 430, and simulator 432. The components in the example simulation framework 400 are merely illustrative examples provided for explanation purposes. In other examples, the simulation framework 400 can include other components that are not shown in FIG. 4 and/or more or less components than shown in FIG. 4.

The data sources 402 can be used to create a simulation. The data sources 402 can include, for example and without limitation, one or more crash databases 404, road sensor data 406, map data 408, and/or synthetic data 410. In other examples, the data sources 402 can include more or less sources than shown in FIG. 4 and/or one or more data sources that are not shown in FIG. 4. In an illustrative example, the data sources 402 can include AV road data 302 and/or scene datasets 308 that are extracted from AV road data 302.

The crash databases 404 can include crash data (e.g., data describing crashes and/or associated details) generated by vehicles involved in crashes. The road sensor data 406 can include data collected by one or more sensors (e.g., one or more camera sensors, LiDAR sensors, RADAR sensors, SONAR sensors, IMU sensors, GPS/GNSS receivers, and/or any other sensors) of one or more vehicles while the one or more vehicles drive/navigate one or more real-world environments. The map data 408 can include one or more maps (and, in some cases, associated data) such as, for example and without limitation, one or more high-definition (HD) maps, sensor maps, scene maps, and/or any other maps. In some examples, the one or more HD maps can include roadway information such as, for example, lane widths, location of road signs and traffic lights, directions of travel for each lane, road junction information, speed limit information, etc.

The synthetic data 410 can include virtual assets, objects, and/or elements created for a simulated scene, a virtual scene and/or virtual scene elements, and/or any other synthetic data elements. For example, in some cases, the synthetic data 410 can include one or more virtual vehicles, virtual pedestrians, virtual roads, virtual objects, virtual environments/scenes, virtual signs, virtual backgrounds, virtual buildings, virtual trees, virtual motorcycles/bicycles, virtual obstacles, virtual environmental elements (e.g., weather, lightening, shadows, etc.), virtual surfaces, etc. In some aspects, the synthetic data 410 can include synthetic sensor data such as synthetic camera data, synthetic LiDAR data, synthetic RADAR data, synthetic IMU data, and/or any other type of synthetic sensor data.

In some examples, data from some or all of the data sources 402 can be used to create the content 412. The content 412 can include static content and/or dynamic content. For example, the content 412 can include roadway information 414, maneuvers 416, scenarios 418, signage 420, traffic 422, co-simulation 424, and/or data replay 426. The roadway information 414 can include, for example, lane information (e.g., number of lanes, lane widths, directions of travel for each lane, etc.), the location and information of road signs and/or traffic lights, road junction information, speed limit information, road attributes (e.g., surfaces, angles of inclination, curvatures, obstacles, etc.), road topologies, and/or other roadway information. The maneuvers 416 can include any AV maneuvers, and the scenarios 418 can include specific AV behaviors in certain AV scenes/environments. The signage 420 can include signs such as, for example, traffic lights, road signs, billboards, displayed messages on the road, etc. The traffic 422 can include any traffic information such as, for example, traffic density, traffic fluctuations, traffic patterns, traffic activity, delays, positions of traffic, velocities, volumes of vehicles in traffic, geometries or footprints of vehicles, pedestrians, spaces (occupied and/or unoccupied), etc.

The co-simulation 424 can include a distributed modeling and simulation of different AV subsystems that form the larger AV system. In some cases, the co-simulation 424 can include information for connecting separate simulations together with interactive communications. In some cases, the co-simulation 424 can allow for modeling to be done at a subsystem level while providing interfaces to connect the subsystems to the rest of the system (e.g., the autonomous driving system computer). Moreover, the data replay 426 can include replay content produced from real-world sensor data (e.g., road sensor data 406).

The environmental conditions 428 can include any information about environmental conditions 428. For example, the environmental conditions 428 can include atmospheric conditions, road/terrain conditions (e.g., surface slope or gradient, surface geometry, surface coefficient of friction, road obstacles, etc.), illumination, weather, road and/or scene conditions resulting from one or more environmental conditions, etc.

The content 412 and the environmental conditions 428 can be used to create the parameterization 430. The parameterization 430 can include parameter ranges, parameterized scenarios, probability density functions of one or more parameters, sampled parameter values, parameter spaces to be tested, evaluation windows for evaluating a behavior of an AV in a simulation, scene parameters, content parameters, environmental parameters, etc. The parameterization 430 can be used by a simulator 432 to generate a simulation 440.

The simulator 432 can include a software engine(s), algorithm(s), neural network model(s), and/or software component(s) used to generate simulations, such as simulation 440. In some examples, the simulator 432 can include autonomous driving system computer (ADSC)/subsystem models 434, sensor models 436, and a vehicle dynamics model 438. The ADSC/subsystem models 434 can include models, descriptors, and/or interfaces for the ADSC and/or ADSC subsystems such as, for example, a perception stack (e.g., perception stack 112), a localization stack (e.g., localization stack 114), a prediction stack (e.g., prediction stack 116), a planning stack (e.g., planning stack 118), a communications stack (e.g., communications stack 120), a control stack (e.g., control stack 122), a sensor system(s), and/or any other subsystems.

The sensor models 436 can include mathematical representations of hardware sensors and an operation (e.g., sensor data processing) of one or more sensors (e.g., a LiDAR, a RADAR, a SONAR, a camera sensor, an IMU, and/or any other sensor). For example, sensor models 436 can include a LiDAR sensor model that simulates operation of a LiDAR sensor. That is, a LiDAR sensor model can be used to simulate transmission of LiDAR beams in the simulation 440 and can simulate LiDAR measurements such as range, intensity, etc. corresponding to one or more objects in the simulation 440. The vehicle dynamics model 438 can model vehicle behaviors/operations, vehicle attributes, vehicle trajectories, vehicle positions, etc.

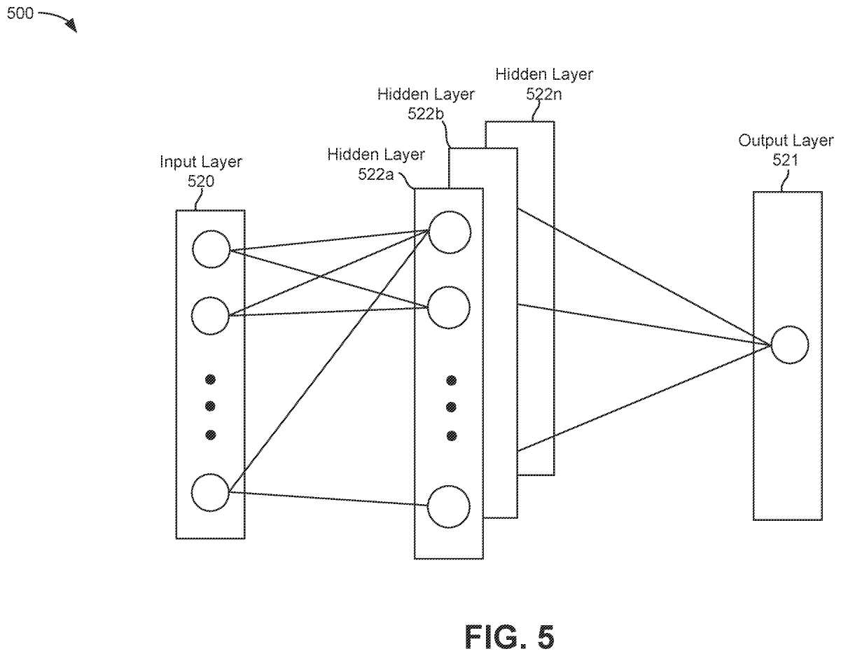

In FIG. 5, the disclosure now turns to a further discussion of models that can be used through the environments and techniques described herein. FIG. 5 is an example of a deep learning neural network 500 that can be used to implement all or a portion of the systems and techniques described herein (e.g., neural network 500 can be used to implement a scene selector as discussed above). In some aspects, neural network 500 can include input layer 520 (e.g., configured to receive one or more inputs); hidden layers 522a, 522b, through 522n (e.g., “n” hidden layers as needed for the given application); and output layer 521 (e.g., configured to provide output resulting from the processing performed by the hidden layers). In one illustrative example, input layer 520 can be configured to receive a scene selection or an AV detection (e.g., school bus, construction zone, road closure, etc.) and output layer 521 can identify one or more features associated with the scene (e.g., object type(s), object size(s), object action(s), detection time(s), map location(s), etc.).

The neural network 500 is a multi-layer neural network of interconnected nodes. Each node can represent a piece of information. Information associated with the nodes is shared among the different layers and each layer retains information as information is processed. In some cases, the neural network 500 can include a feed-forward network, in which case there are no feedback connections where outputs of the network are fed back into itself. In some cases, the neural network 500 can include a recurrent neural network, which can have loops that allow information to be carried across nodes while reading in input.

Information can be exchanged between nodes through node-to-node interconnections between the various layers. Nodes of the input layer 520 can activate a set of nodes in the first hidden layer 522a. For example, as shown, each of the input nodes of the input layer 520 is connected to each of the nodes of the first hidden layer 522a. The nodes of the first hidden layer 522a can transform the information of each input node by applying activation functions to the input node information. The information derived from the transformation can then be passed to and can activate the nodes of the next hidden layer 522b, which can perform their own designated functions. Example functions include convolutional, up-sampling, data transformation, and/or any other suitable functions. The output of the hidden layer 522b can then activate nodes of the next hidden layer, and so on. The output of the last hidden layer 522n can activate one or more nodes of the output layer 521, at which an output is provided. In some cases, while nodes in the neural network 500 are shown as having multiple output lines, a node can have a single output and all lines shown as being output from a node represent the same output value.

In some cases, each node or interconnection between nodes can have a weight that is a set of parameters derived from the training of the neural network 500. Once the neural network 500 is trained, it can be referred to as a trained neural network, which can be used to classify one or more activities. For example, an interconnection between nodes can represent a piece of information learned about the interconnected nodes. The interconnection can have a tunable numeric weight that can be tuned (e.g., based on a training dataset), allowing the neural network 500 to be adaptive to inputs and able to learn as more and more data is processed.

The neural network 500 is pre-trained to process the features from the data in the input layer 520 using the different hidden layers 522a, 522b, through 522n in order to provide the output through the output layer 521.

In some cases, the neural network 500 can adjust the weights of the nodes using a training process called backpropagation. A backpropagation process can include a forward pass, a loss function, a backward pass, and a weight update. The forward pass, loss function, backward pass, and parameter/weight update is performed for one training iteration. The process can be repeated for a certain number of iterations for each set of training data until the neural network 500 is trained well enough so that the weights of the layers are accurately tuned.

To perform training, a loss function can be used to analyze error in the output. Any suitable loss function definition can be used, such as a Cross-Entropy loss. Another example of a loss function includes the mean squared error (MSE), defined as E_total=Σ(½ (target-output)^{∧}2). The loss can be set to be equal to the value of E_total.

The loss (or error) will be high for the initial training data since the actual values will be much different than the predicted output. The goal of training is to minimize the amount of loss so that the predicted output is the same as the training output. The neural network 500 can perform a backward pass by determining which inputs (weights) most contributed to the loss of the network, and can adjust the weights so that the loss decreases and is eventually minimized.

The neural network 500 can include any suitable deep network. One example includes a Convolutional Neural Network (CNN), which includes an input layer and an output layer, with multiple hidden layers between the input and out layers. The hidden layers of a CNN include a series of convolutional, nonlinear, pooling (for downsampling), and fully connected layers. The neural network 500 can include any other deep network other than a CNN, such as an autoencoder, Deep Belief Nets (DBNs), Recurrent Neural Networks (RNNs), among others.

As understood by those of skill in the art, machine-learning based classification techniques can vary depending on the desired implementation. For example, machine-learning classification schemes can utilize one or more of the following, alone or in combination: hidden Markov models; RNNs; CNNs; deep learning; Bayesian symbolic methods; Generative Adversarial Networks (GANs); support vector machines; image registration methods; and applicable rule-based systems. Where regression algorithms are used, they may include but are not limited to: a Stochastic Gradient Descent Regressor, a Passive Aggressive Regressor, etc.

Machine learning classification models can also be based on clustering algorithms (e.g., a Mini-batch K-means clustering algorithm), a recommendation algorithm (e.g., a Minwise Hashing algorithm, or Euclidean Locality-Sensitive Hashing (LSH) algorithm), and/or an anomaly detection algorithm, such as a local outlier factor. Additionally, machine-learning models can employ a dimensionality reduction approach, such as, one or more of: a Mini-batch Dictionary Learning algorithm, an incremental Principal Component Analysis (PCA) algorithm, a Latent Dirichlet Allocation algorithm, and/or a Mini-batch K-means algorithm, etc.

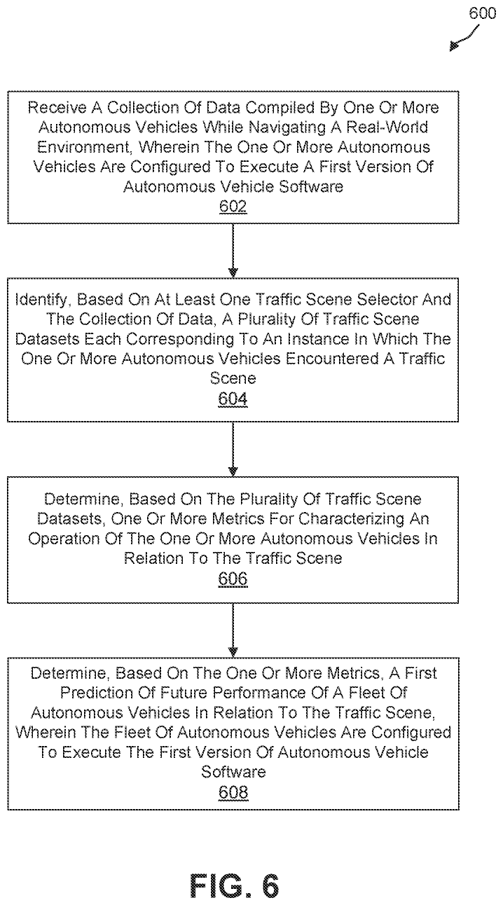

FIG. 6 illustrates a flowchart of an example process 600 for characterizing and predicting performance of autonomous vehicles in relation to selected traffic scenes. At step 602, the process 600 includes receiving a collection of data compiled by one or more autonomous vehicles while navigating a real-world environment, wherein the one or more autonomous vehicles are configured to execute a first version of autonomous vehicle software. For example, system 300 can receive AV road data 302 from AV 102.

At step 604, the process 600 includes identifying, based on at least one traffic scene selector and the collection of data, a plurality of traffic scene datasets each corresponding to an instance in which the one or more autonomous vehicles encountered a traffic scene. For example, system 300 may include scene selector 306 that can be configured to identify scene datasets corresponding to an instance in which AV 102 encountered a traffic scene.

In some aspects, the at least one traffic scene selector can include at least one of an autonomous vehicle detector, a detector confidence level, and a scene descriptor. In some cases, the scene descriptor can include at least one of an object type, an object size, an object action, an object orientation, an object location, and a map location. In some aspects, the traffic scene can correspond to a temporary traffic scene, and the temporary traffic scene can include at least one of a school bus, a human controlling traffic, a road closure, a construction zone, a traffic redirection, a traffic blockage, and an emergency vehicle.

At step 606, the process 600 includes determining, based on the plurality of traffic scene datasets, one or more metrics for characterizing an operation of the one or more autonomous vehicles in relation to the traffic scene. For instance, system 300 may include AV performance characterization module 310 which may determine metrics 312 for characterizing the operation of AV 102 based on scene datasets 308. In some examples, the one or more metrics for characterizing the operation of the one or more autonomous vehicles in relation to the traffic scene can include at least one of an exposure rate, a precision metric, and a recall metric.

At step 608, the process 600 includes determining, based on the one or more metrics, a first prediction of future performance of a fleet of autonomous vehicles in relation to the traffic scene, wherein the fleet of autonomous vehicles are configured to execute the first version of autonomous vehicle software. For example, system 300 may include AV performance characterization module 310 which may determine predictions 320 based on metrics 312.

In some examples, the process 600 can include performing one or more simulated tests of the first version of autonomous vehicle software using a simulation environment configured to implement one or more simulation test scenarios, wherein at least a portion of the one or more simulation test scenarios are based on one or more of the plurality of traffic scene datasets. For instance, system 300 can include simulation environment 316 that can be configured to execute simulation test scenarios generated by simulation test generator 314 that are based on one or more of scene datasets 308.

In some cases, the process 600 can include determining, based on the one or more simulated tests, one or more additional metrics for characterizing the operation of the first version of autonomous vehicle software in relation to the traffic scene and updating, based on the one or more additional metrics, the first prediction of future performance of the fleet of autonomous vehicles in relation to the traffic scene. For example, AV performance characterization module 310 can determine metrics 312 that are based on simulated tests that are based on scene datasets 308 and are executed using simulation environment 316. In some aspects, AV performance characterization module 310 can update prediction 320 based on one or more additional metrics (e.g., metrics 312) corresponding to the simulated tests.

In some aspects, the process 600 can include performing one or more simulated tests of a second version of autonomous vehicle software using a simulation environment configured to implement one or more simulation test scenarios, wherein at least a portion of the one or more simulation test scenarios are based on one or more of the plurality of traffic scene datasets. For example, system 300 can include simulation environment 316 that can be configured to execute simulation test scenarios generated by simulation test generator 314 that are based on one or more of scene datasets 308. Simulation environment 316 can be used to test different version of AV software 318.

In some cases, the process 600 can include determining, based on the one or more simulated tests, one or more revised metrics for characterizing the operation of the second version of autonomous vehicle software in relation to the traffic scene and determining, based on the one or more revised metrics, a second prediction of future performance of the fleet of autonomous vehicles in relation to the traffic scene, wherein the fleet of autonomous vehicles are configured to execute the second version of autonomous vehicle software. For example, AV performance characterization module 310 can determine, based on simulated tests executed by simulation environment 316, one or more revised metrics (e.g., metrics 312) for characterizing the operation of the second version of AV software 318. In some aspects, AV performance characterization module 310 can determine, based on the revised metrics 312, a second prediction (e.g., predictions 320) of future performance of the fleet of AVs in relation to the traffic scene (e.g., the traffic scene associated with scene datasets 308).

FIG. 7 illustrates an example processor-based system with which some aspects of the subject technology can be implemented. For example, processor-based system 700 can be any computing device making up local computing device 110, client computing device 170, a passenger device executing the ridesharing application 172, or any component thereof in which the components of the system are in communication with each other using connection 705. Connection 705 can be a physical connection via a bus, or a direct connection into processor 710, such as in a chipset architecture. Connection 705 can also be a virtual connection, networked connection, or logical connection.

In some examples, computing system 700 is a distributed system in which the functions described in this disclosure can be distributed within a datacenter, multiple data centers, a peer network, etc. In some cases, one or more of the described system components represents many such components each performing some or all of the function for which the component is described. In some cases, the components can be physical or virtual devices.

Example system 700 includes at least one processing unit (CPU or processor) 710 and connection 705 that couples various system components including system memory 715, such as read-only memory (ROM) 720 and random-access memory (RAM) 725 to processor 710. Computing system 700 can include a cache of high-speed memory 712 connected directly with, in close proximity to, and/or integrated as part of processor 710.

Processor 710 can include any general-purpose processor and a hardware service or software service, such as services 732, 734, and 736 stored in storage device 730, configured to control processor 710 as well as a special-purpose processor where software instructions are incorporated into the actual processor design. Processor 710 may essentially be a completely self-contained computing system, containing multiple cores or processors, a bus, memory controller, cache, etc. A multi-core processor may be symmetric or asymmetric.

To enable user interaction, computing system 700 can include an input device 745, which can represent any number of input mechanisms, such as a microphone for speech, a touch-sensitive screen for gesture or graphical input, keyboard, mouse, motion input, speech, etc. Computing system 700 can also include output device 735, which can be one or more of a number of output mechanisms known to those of skill in the art. In some instances, multimodal systems can enable a user to provide multiple types of input/output to communicate with computing system 700. Computing system 700 can include communications interface 740, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/9G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communications interface 740 may also include one or more Global Navigation Satellite System (GNSS) receivers or transceivers that are used to determine a location of the computing system 700 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 730 can be a non-volatile and/or non-transitory computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L9/L #), resistive random-access memory (RRAM/ReRAM), phase change memory (PCM), spin transfer torque RAM (STT-RAM), another memory chip or cartridge, and/or a combination thereof.

Storage device 730 can include software services, servers, services, etc., that when the code that defines such software is executed by the processor 710, causes the system to perform a function. In some examples, a hardware service that performs a particular function can include the software component stored in a computer-readable medium in connection with the necessary hardware components, such as processor 710, connection 705, output device 735, etc., to carry out the function.

Aspects within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special-purpose computer, or special-purpose processing device to perform a certain function or group of functions. By way of example, computer-executable instructions can be used to implement perception system functionality for determining when sensor cleaning operations are needed or should begin. Computer-executable instructions can also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other examples of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Aspects of the disclosure may also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

The various examples described above are provided by way of illustration only and should not be construed to limit the scope of the disclosure. For example, the principles herein apply equally to optimization as well as general improvements. Various modifications and changes may be made to the principles described herein without following the example aspects and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:

Aspect 1. A method comprising: receiving a collection of data compiled by one or more autonomous vehicles while navigating a real-world environment, wherein the one or more autonomous vehicles are configured to execute a first version of autonomous vehicle software; identifying, based on at least one traffic scene selector and the collection of data, a plurality of traffic scene datasets each corresponding to an instance in which the one or more autonomous vehicles encountered a traffic scene; determining, based on the plurality of traffic scene datasets, one or more metrics for characterizing an operation of the one or more autonomous vehicles in relation to the traffic scene; and determining, based on the one or more metrics, a first prediction of future performance of a fleet of autonomous vehicles in relation to the traffic scene, wherein the fleet of autonomous vehicles are configured to execute the first version of autonomous vehicle software.

Aspect 2. The method of Aspect 1, further comprising: performing one or more simulated tests of the first version of autonomous vehicle software using a simulation environment configured to implement one or more simulation test scenarios, wherein at least a portion of the one or more simulation test scenarios are based on one or more of the plurality of traffic scene datasets; determining, based on the one or more simulated tests, one or more additional metrics for characterizing the operation of the first version of autonomous vehicle software in relation to the traffic scene; and updating, based on the one or more additional metrics, the first prediction of future performance of the fleet of autonomous vehicles in relation to the traffic scene.

Aspect 3. The method of any of Aspects 1 to 2, further comprising: performing one or more simulated tests of a second version of autonomous vehicle software using a simulation environment configured to implement one or more simulation test scenarios, wherein at least a portion of the one or more simulation test scenarios are based on one or more of the plurality of traffic scene datasets; determining, based on the one or more simulated tests, one or more revised metrics for characterizing the operation of the second version of autonomous vehicle software in relation to the traffic scene; and determining, based on the one or more revised metrics, a second prediction of future performance of the fleet of autonomous vehicles in relation to the traffic scene, wherein the fleet of autonomous vehicles are configured to execute the second version of autonomous vehicle software.

Aspect 4. The method of any of Aspects 1 to 3, wherein the at least one traffic scene selector includes at least one of an autonomous vehicle detector, a detector confidence level, and a scene descriptor.

Aspect 5. The method of Aspect 4, wherein the scene descriptor includes at least one of an object type, an object size, an object action, and a map location.

Aspect 6. The method of any of Aspects 1 to 5, wherein the traffic scene corresponds to a temporary traffic scene, and wherein the temporary traffic scene includes at least one of a school bus, a human controlling traffic, a road closure, a construction zone, a traffic redirection, a traffic blockage, and an emergency vehicle.

Aspect 7. The method of any of Aspects 1 to 6, wherein the one or more metrics for characterizing the operation of the one or more autonomous vehicles in relation to the traffic scene include at least one of an exposure rate, a precision metric, and a recall metric.

Aspect 8. An apparatus comprising: at least one memory; and at least one processor coupled to the at least one memory, wherein the at least one processor is configured to perform operations in accordance with any one of Aspects 1 to 7.

Aspect 9. An apparatus comprising means for performing operations in accordance with any one of Aspects 1 to 7.

Aspect 10. A non-transitory computer-readable medium comprising instructions that, when executed by an apparatus, cause the apparatus to perform operations in accordance with any one of Aspects 1 to 7.

What is claimed is:

1. A system comprising:
a memory; and
one or more processors coupled to the memory, the one or more processors being configured to:
receive a collection of data compiled by one or more autonomous vehicles while navigating a real-world environment, wherein the one or more autonomous vehicles are configured to execute a first version of autonomous vehicle software;
identify, based on at least one traffic scene selector and the collection of data, a plurality of traffic scene datasets each corresponding to an instance in which the one or more autonomous vehicles encountered a traffic scene;
determine, based on the plurality of traffic scene datasets, one or more metrics for characterizing an operation of the one or more autonomous vehicles in relation to the traffic scene; and
determine, based on the one or more metrics, a first prediction of future performance of a fleet of autonomous vehicles in relation to the traffic scene, wherein the fleet of autonomous vehicles are configured to execute the first version of autonomous vehicle software.

2. The system of claim 1, wherein the one or more processors are further configured to:
perform one or more simulated tests of the first version of autonomous vehicle software using a simulation environment configured to implement one or more simulation test scenarios, wherein at least a portion of the one or more simulation test scenarios are based on one or more of the plurality of traffic scene datasets;
determine, based on the one or more simulated tests, one or more additional metrics for characterizing the operation of the first version of autonomous vehicle software in relation to the traffic scene; and
update, based on the one or more additional metrics, the first prediction of future performance of the fleet of autonomous vehicles in relation to the traffic scene.

3. The system of claim 1, wherein the one or more processors are further configured to:
perform one or more simulated tests of a second version of autonomous vehicle software using a simulation environment configured to implement one or more simulation test scenarios, wherein at least a portion of the one or more simulation test scenarios are based on one or more of the plurality of traffic scene datasets;
determine, based on the one or more simulated tests, one or more revised metrics for characterizing the operation of the second version of autonomous vehicle software in relation to the traffic scene; and
determine, based on the one or more revised metrics, a second prediction of future performance of the fleet of autonomous vehicles in relation to the traffic scene, wherein the fleet of autonomous vehicles are configured to execute the second version of autonomous vehicle software.

4. The system of claim 1, wherein the at least one traffic scene selector includes at least one of an autonomous vehicle detector, a detector confidence level, and a scene descriptor.

5. The system of claim 4, wherein the scene descriptor includes at least one of an object type, an object size, an object action, and a map location.

6. The system of claim 1, wherein the traffic scene corresponds to a temporary traffic scene, and wherein the temporary traffic scene includes at least one of a stopped school bus, a human controlling traffic, a road closure, a construction zone, a traffic redirection, a traffic blockage, and an emergency vehicle.

7. The system of claim 1, wherein the one or more metrics for characterizing the operation of the one or more autonomous vehicles in relation to the traffic scene include at least one of an exposure rate, a precision metric, and a recall metric.

8. A method comprising:
receiving a collection of data compiled by one or more autonomous vehicles while navigating a real-world environment, wherein the one or more autonomous vehicles are configured to execute a first version of autonomous vehicle software;
identifying, based on at least one traffic scene selector and the collection of data, a plurality of traffic scene datasets each corresponding to an instance in which the one or more autonomous vehicles encountered a traffic scene;
determining, based on the plurality of traffic scene datasets, one or more metrics for characterizing an operation of the one or more autonomous vehicles in relation to the traffic scene; and
determining, based on the one or more metrics, a first prediction of future performance of a fleet of autonomous vehicles in relation to the traffic scene, wherein the fleet of autonomous vehicles are configured to execute the first version of autonomous vehicle software.

9. The method of claim 8, further comprising:
performing one or more simulated tests of the first version of autonomous vehicle software using a simulation environment configured to implement one or more simulation test scenarios, wherein at least a portion of the one or more simulation test scenarios are based on one or more of the plurality of traffic scene datasets;
determining, based on the one or more simulated tests, one or more additional metrics for characterizing the operation of the first version of autonomous vehicle software in relation to the traffic scene; and
updating, based on the one or more additional metrics, the first prediction of future performance of the fleet of autonomous vehicles in relation to the traffic scene.

10. The method of claim 8, further comprising:
performing one or more simulated tests of a second version of autonomous vehicle software using a simulation environment configured to implement one or more simulation test scenarios, wherein at least a portion of the one or more simulation test scenarios are based on one or more of the plurality of traffic scene datasets;
determining, based on the one or more simulated tests, one or more revised metrics for characterizing the operation of the second version of autonomous vehicle software in relation to the traffic scene; and
determining, based on the one or more revised metrics, a second prediction of future performance of the fleet of autonomous vehicles in relation to the traffic scene, wherein the fleet of autonomous vehicles are configured to execute the second version of autonomous vehicle software.

11. The method of claim 8, wherein the at least one traffic scene selector includes at least one of an autonomous vehicle detector, a detector confidence level, and a scene descriptor.

12. The method of claim 11, wherein the scene descriptor includes at least one of an object type, an object size, an object action, and a map location.

13. The method of claim 8, wherein the traffic scene corresponds to a temporary traffic scene, and wherein the temporary traffic scene includes at least one of a school bus, a human controlling traffic, a road closure, a construction zone, a traffic redirection, a traffic blockage, and an emergency vehicle.

14. The method of claim 8, wherein the one or more metrics for characterizing the operation of the one or more autonomous vehicles in relation to the traffic scene include at least one of an exposure rate, a precision metric, and a recall metric.

15. A non-transitory computer-readable media comprising instructions stored thereon which, when executed are configured to cause a computer or processor to:
receive a collection of data compiled by one or more autonomous vehicles while navigating a real-world environment, wherein the one or more autonomous vehicles are configured to execute a first version of autonomous vehicle software;
identify, based on at least one traffic scene selector and the collection of data, a plurality of traffic scene datasets each corresponding to an instance in which the one or more autonomous vehicles encountered a traffic scene;
determine, based on the plurality of traffic scene datasets, one or more metrics for characterizing an operation of the one or more autonomous vehicles in relation to the traffic scene; and
determine, based on the one or more metrics, a first prediction of future performance of a fleet of autonomous vehicles in relation to the traffic scene, wherein the fleet of autonomous vehicles are configured to execute the first version of autonomous vehicle software.

16. The non-transitory computer-readable media of claim 15, comprising further instructions configured to cause the computer or the processor to:
perform one or more simulated tests of the first version of autonomous vehicle software using a simulation environment configured to implement one or more simulation test scenarios, wherein at least a portion of the one or more simulation test scenarios are based on one or more of the plurality of traffic scene datasets;
determine, based on the one or more simulated tests, one or more additional metrics for characterizing the operation of the first version of autonomous vehicle software in relation to the traffic scene; and
update, based on the one or more additional metrics, the first prediction of future performance of the fleet of autonomous vehicles in relation to the traffic scene.

17. The non-transitory computer-readable media of claim 15, comprising further instructions configured to cause the computer or the processor to:
perform one or more simulated tests of a second version of autonomous vehicle software using a simulation environment configured to implement one or more simulation test scenarios, wherein at least a portion of the one or more simulation test scenarios are based on one or more of the plurality of traffic scene datasets;
determine, based on the one or more simulated tests, one or more revised metrics for characterizing the operation of the second version of autonomous vehicle software in relation to the traffic scene; and
determine, based on the one or more revised metrics, a second prediction of future performance of the fleet of autonomous vehicles in relation to the traffic scene, wherein the fleet of autonomous vehicles are configured to execute the second version of autonomous vehicle software.

18. The non-transitory computer-readable media of claim 15, wherein the at least one traffic scene selector includes at least one of an autonomous vehicle detector, a detector confidence level, and a scene descriptor.

19. The non-transitory computer-readable media of claim 15, wherein the traffic scene corresponds to a temporary traffic scene, and wherein the temporary traffic scene includes at least one of a school bus, a human controlling traffic, a road closure, a construction zone, a traffic redirection, a traffic blockage, and an emergency vehicle.

20. The non-transitory computer-readable media of claim 15, wherein the one or more metrics for characterizing the operation of the one or more autonomous vehicles in relation to the traffic scene include at least one of an exposure rate, a precision metric, and a recall metric.
